(19) United States
(12) Patent Application Publication
(10) Pub. No.: US 2006/0244076 A1
(43) Pub. Date: Nov. 2, 2006

(54) Semiconductor storage device and method of fabricating the same

(75) Inventor: Takeshi Hamamoto, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/261,537

(22) Filed: Oct. 31, 2005

(30) Foreign Application Priority Data
Apr. 28, 2005 (JP) 2005-132481

(51) Int. Cl. H01L 29/76

(52) U.S. Cl. 257/391

(57) ABSTRACT

A semiconductor storage device, has a first conductive type semiconductor region formed on a semiconductor substrate, a plurality of second conductive type semiconductor regions formed separately from each other on the first conductive type semiconductor region, a plurality of MOSFETs each formed on the plurality of second conductive type semiconductor regions, and element isolating regions each formed between the adjacent second conductive type semiconductor regions, a bottom surface of which being located in the first conductive type semiconductor region, wherein the number of crystal defects per unit volume in the first conductive type semiconductor region is larger than the number of the crystal defects per unit volume in the second conductive type semiconductor regions.

### CROSS REFERENCE TO RELATED APPLICATIONS

This application is based upon and claims the benefit of priority from the prior Japanese Patent Application No. 2005-132481, filed on Apr. 28, 2005, the entire contents of which are incorporated herein by reference.

### BACKGROUND OF THE INVENTION

1. Field of the Invention

The present invention relates to a semiconductor storage device in which MOSFETs sandwich an element isolating region and are arranged on its both sides, and a method of fabricating the semiconductor storage device.

2. Related Art

The conventional DRAM cell includes a capacitor for storing signal charges and a MOSFET for switching. The capacitance of the capacitor is generally required to be an order of 30 pF. Even if the design rule is scaled down for the purpose of higher integration, it is required to keep 30 pF to stabilize the operation of the DRAM cell. Therefore, a process modification such as thinning of an insulating film of a stacked capacitor or a trench capacitor is required.

On the contrary, a DRAM cell configured with a MOSFET using no capacitor has been proposed (see Technical Papers of R. Ranica, et al., 2004 Symposium on VLSI Technology Digest). Such kind of DRAM cell has a MOS transistor formed on a silicon substrate, and holes being signal charges are stored in a P-well of the transistor. The DRAM cell is utilized as a storage device by using a phenomenon that the threshold values of the MOSFET are different depending on whether the holes exist or not.

In such kind of DRAM, in order to isolate between neighboring memory cells, an STI is provided between both memory cells, and a buried N-well region is formed on the bottom of the P-well region within each memory cell to isolate the cell from a silicon substrate.

As for the example of the application of the above DRAM cell having no capacitor, there is a hybrid device having a logic device and a DRAM (see Japanese Patent Laid-Open Publication No. 2003-51551). By using a MOS transistor as a memory cell, it is possible to provide a large scale logic memory cell without increasing the number of processes.

However, the conventional technology has a problem that signal breakdown due to a parasitic bipolar transistor occurs. That is, holes accumulated in a P-well region of one of two memory cells which sandwiches an STI and are arranged on its both sides will flow into the other memory cell through an N-well region. This means that charges accumulated in the original P-well region will disappear and become a reason of a malfunction of the memory cell. This phenomenon is referred to as “bipolar disturb”.

In order to prevent the phenomenon from occurring, it is required to provide constraint on a biasing condition to be applied to the memory cell. However, signal charges will decrease due to the constraint, thereby, it will be difficult to extract the peculiar characteristics of the memory cell. If the power voltage fluctuates due to noises during the operation of the memory cell, the fluctuation may cause occurrence of a bipolar disturb, resulting in a malfunction.

### SUMMARY OF THE INVENTION

According to one embodiment of the present invention, a semiconductor storage device, comprising:

a first conductive type semiconductor region formed on a semiconductor substrate;

a plurality of second conductive type semiconductor regions formed separately from each other on the first conductive type semiconductor region;

a plurality of MOSFETs each formed on the plurality of second conductive type semiconductor regions; and

element isolating regions each formed between the adjacent second conductive type semiconductor regions, a bottom surface of which being located in the first conductive type semiconductor region,

wherein the number of crystal defects per unit volume in the first conductive type semiconductor region is larger than the number of the crystal defects per unit volume in the second conductive type semiconductor regions.

Furthermore, according to one embodiment of the present invention, a method of fabricating a semiconductor storage device, comprising:

forming a plurality of trenches separate from each other on a semiconductor substrate;

filling an insulating material in the trenches to form a plurality of element isolating regions;

injecting impurity ions of conductive type different from that of the semiconductor substrate to form a first conductive type semiconductor region which overlaps in the vicinity of bottom surfaces of the element isolating regions and second conductive type semiconductor regions on both sides of the element isolating regions on the first conductive type semiconductor region;

forming crystal defects in the first conductive type semiconductor region; and

forming MOSFETs in the plurality of second conductive type semiconductor regions.

Furthermore, according to one embodiment of the present invention, a method of fabricating a semiconductor storage device, comprising:

forming a plurality of trenches separate from each other on a semiconductor substrate;

forming crystal defects below bottom surfaces of the trenches, and filling an insulating material in the trenches to form a plurality of element isolating regions;

injecting impurity ions of conductive type different from that of the semiconductor substrate to form a first conductive type semiconductor region which overlaps in the vicinity of bottom surfaces of the element isolating regions and second conductive type semiconductor regions on both sides of the element isolating regions on the first conductive type semiconductor region; and

forming MOSFETs in the plurality of second conductive type semiconductor regions.

### BRIEF DESCRIPTION OF THE DRAWINGS

FIG. 1 is a sectional view of a semiconductor storage device according to the first embodiment of the present invention.

FIG. 2 is a layout view of the semiconductor storage device in the FIG. 1, and the cross section of the dotted part in FIG. 2 is shown in FIG. 1.

FIGS. 3A-3D are views illustrating fabrication processes of the semiconductor storage device in FIG. 1.

FIGS. 4A-4D are views illustrating a vector distribution of positive-hole current 15 in the semiconductor storage device when the N-well region 2 has no crystal defect 6.

FIGS. 5A-5D are views illustrating four semiconductor storage devices having the P-well region 3 with different depths.

FIG. 6 is a graph representing the properties in FIG. 4 more closely.

FIG. 7 is a sectional view of a semiconductor storage device according to the second embodiment of the present invention.

FIGS. 8A-8D are process drawings illustrating fabrication processes of the semiconductor storage device in FIG. 7.

FIG. 9 is a sectional view of a semiconductor storage device according to the third embodiment of the present invention.

FIGS. 10A-10D are process drawings illustrating the fabrication processes of the semiconductor storage device in FIG. 9.

### DETAILED DESCRIPTION OF THE INVENTION

With respect to drawings, one embodiment according to the present invention will be described below.

### First Embodiment

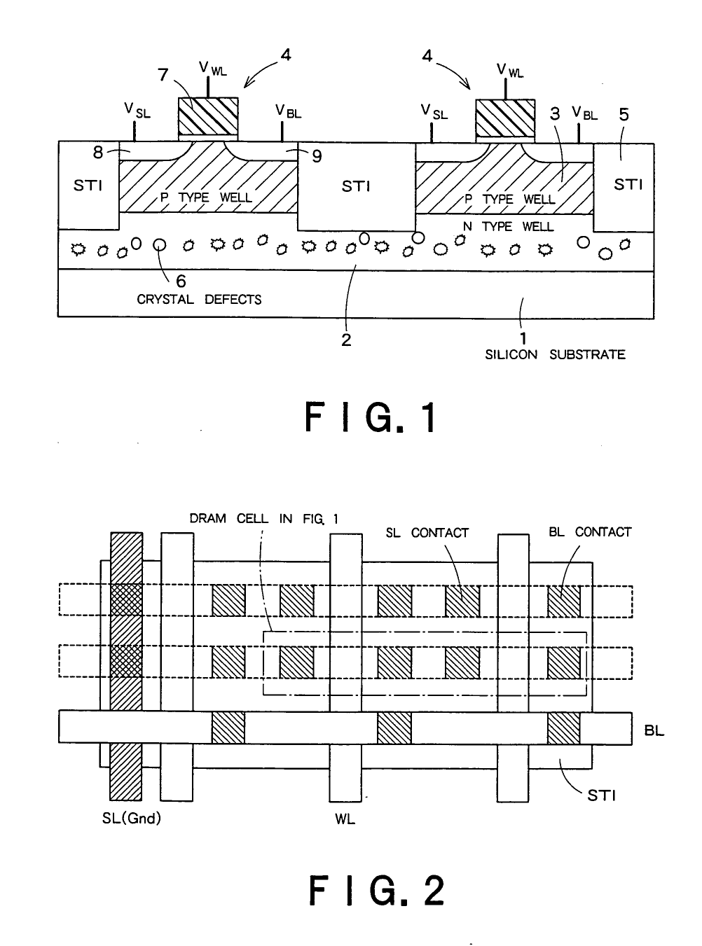

FIG. 1 is a sectional view of a semiconductor storage device according to the first embodiment of the present invention. The semiconductor storage device in FIG. 1 includes an N-well region 2 formed on a silicon substrate 1, a plurality of P-well regions 3 formed on the N-well region 2 separately from each other; a plurality of MOSFETs 4 formed on the P-well regions 3, an element isolating region (STI: Shallow Trench Isolation) 5 formed between adjacent P-well regions 3. The STI 5 reaches the N-well region 2 through the P-well regions 3.

Threshold values of the MOSFETs 4 change depending on the number of holes accumulated in the P-well region 3. Accordingly, in the embodiment, the voltage applied to the MOSFETs 4 is changed according to the storage data to change the number of holes accumulated in the P-well region 3. By detecting the threshold voltages of the MOSFETs 4, logics of storage data are determined. In this way, the MOSFETs 4 can be used as a storage device.

The N-well region 2 has crystal defects 6 intentionally formed, for example by implantation of impurity ions. The crystal defects 6 act to recombine holes flowing from the P-well region 3 with electrons in the N-well region 2. That is, the crystal defects 6 in the N-well region 2 become as recombination centers. Therefore, the possibility that the holes in the P-well region 3 of the MOSFET 4 flow into the P-well region 3 of adjacent MOSFET 4 through the N-well region 2 may be avoided.

FIG. 2 is a layout view of the semiconductor storage device in the FIG. 1, and the cross section of the dotted part in FIG. 2 is shown in FIG. 1. As shown in FIG. 2, MOSFETs 4 are arranged in a matrix, in which the gate electrode 7 of a MOSFET 4 is connected to a word line WL, one of the source electrode 8 and the drain electrode 9 is connected to a source line SL (common electrode), and the other is connected to a bit line BL.

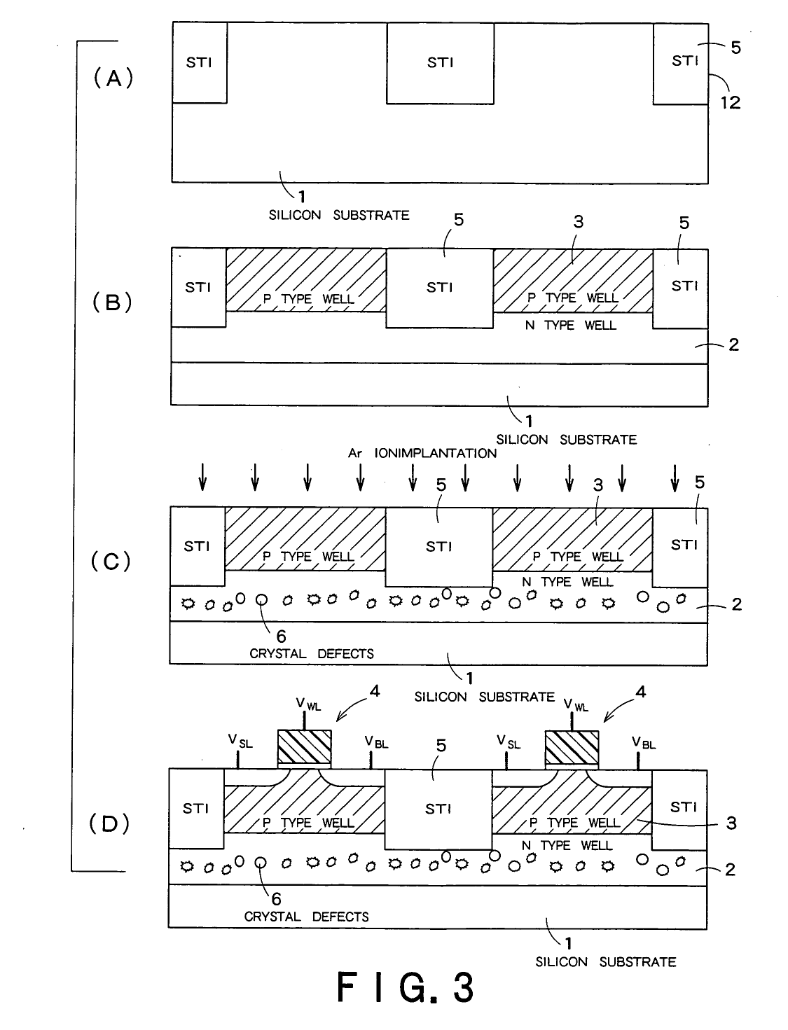

FIGS. 3A-3D are drawings illustrating fabrication processes of the semiconductor storage device in FIG. 1. First, STIs (Shallow Trench Isolation) 5 for isolating MOSFETs 4 are formed on a silicon substrate 1. The STI 5 has, for example, a width of 0.15 μm and a depth of 0.3 μm, for example (FIG. 3A). After trenches 12 are formed, the STIs 5 are formed by filling an insulating material into the trenches 12.

Next, impurity ions (for example, boron) are ion-implanted, for example, at 60 KeV, 5×10¹³ cm⁻², on the entire substrate, to form P-well regions 3 on both sides of the STI 5. Next, impurity ions (for example, phosphorus) are implanted, for example, at 240 KeV, 1×10¹⁴ cm⁻², to form an N-well region 2 on bottom surfaces of the P-well regions 3 (FIG. 3B).

Next, impurity ions (for example, argon) are ion-implanted, for example, at 400 KeV, 1×10¹⁵ cm⁻², and crystal defects 6 are formed in the N-well region 2 (FIG. 3C).

Next, after forming gate electrodes 7 of MOSFETs 4, impurity ions are implanted in the P-well regions 3 to form source regions 8 and drain regions 9 (FIG. 3D). Next, a wiring layer to be connected to each electrode is formed to complete a DRAM cell not having any capacitor.

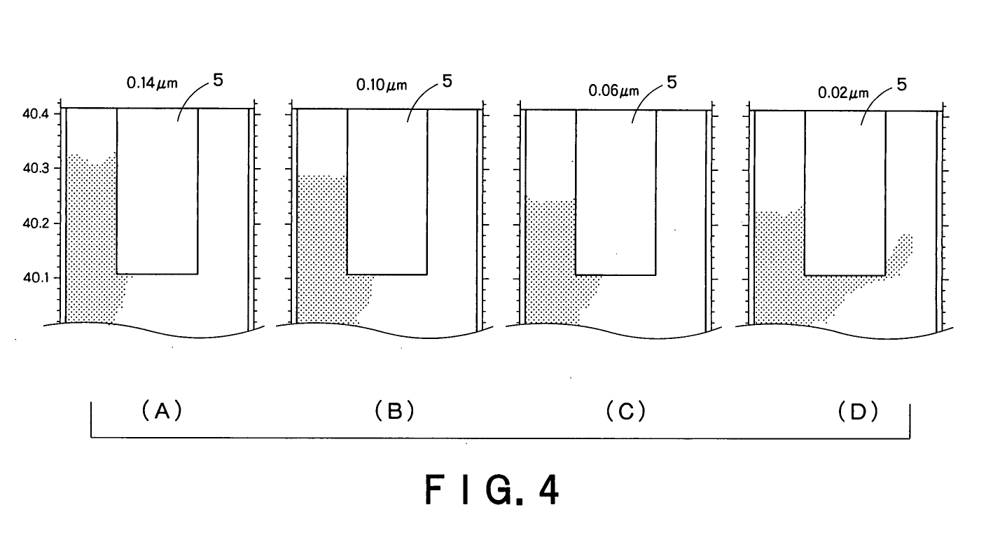

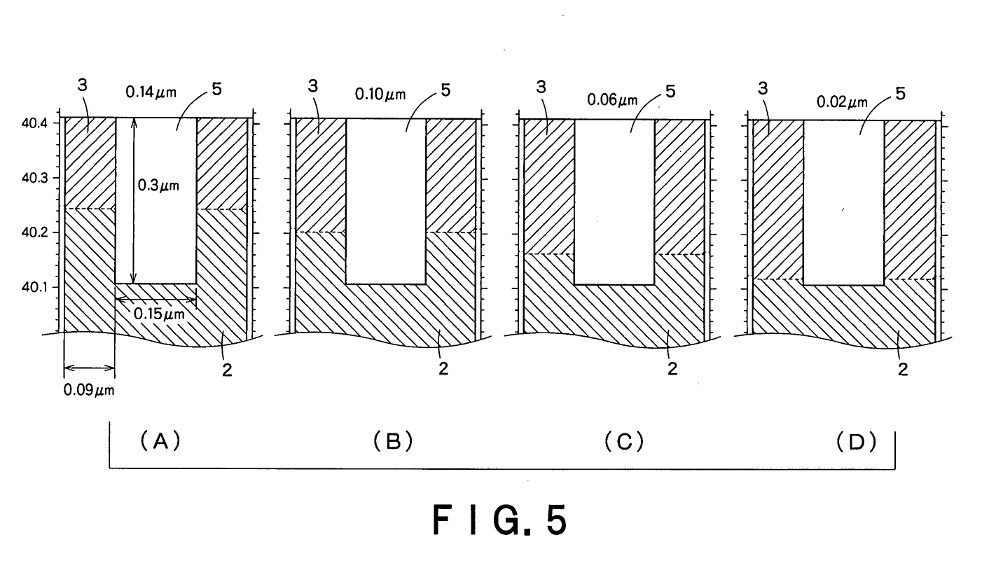

FIGS. 4A-4D are views illustrating a vector distribution of positive-hole current 15 in the semiconductor storage device when the N-well region 2 has no crystal defect 6. FIGS. 4A-4D illustrates the properties of four semiconductor storage devices having the P-well region 3 with different depths, as illustrated in FIGS. 5A-5D. FIG. 4A illustrates the property of the semiconductor storage device having a structure of FIG. 5A, in which the distance from a boundary position between the P-well region 3 and the N-well region 2 to the bottom surface of the STI 5 is, for example, 0.14 μm. FIG. 4B illustrates the property of the semiconductor storage device having a structure of FIG. 5B, in which the distance from boundary position between the P-well region 3 and the N-well region 2 to the bottom surface of the STI 5 is, for example, 0.10 μm. FIG. 4C illustrates the property of the semiconductor storage device having a structure of FIG. 5C, in which the distance from boundary position between the P-well region 3 and the N-well region 2 to the bottom surface of the STI 5 is, for example, 0.06 μm. FIG. 4D illustrates the property of the semiconductor storage device having a structure of FIG. 5D, in which the distance from boundary position between the P-well region 3 and the N-well region 2 to the bottom surface of the STI 5 is, for example, 0.02 μm.

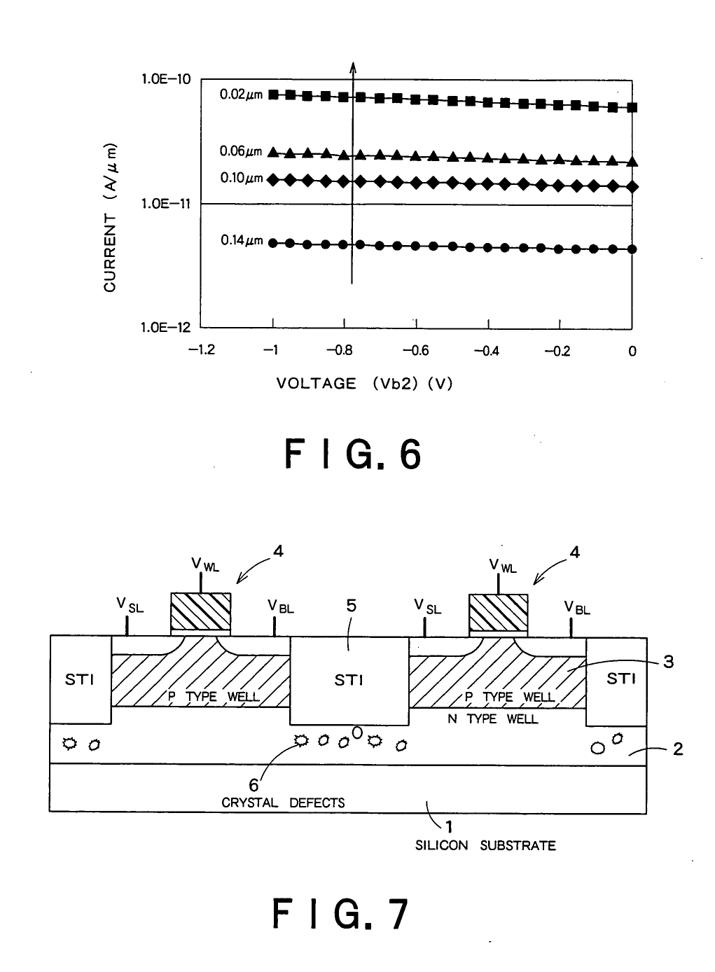

FIG. 6 is a graph representing the properties in FIG. 4 more closely. It is understood that as a junction location of the joint between the P-well region and the N-well region becomes nearer to that of the bottom surface of the STI 5, the positive-hole current increases. On the contrary, in this embodiment, even if the depth of the P-well region 3 is significantly deep, the positive-hole current flowing into the N-well region 2 may be reduced by the crystal defects 6 in the N-well region 2.

In this way, in the first embodiment, crystal defects 6 are formed intentionally in the N-well region 2 for insulating P-well regions 3 of adjacent MOSFETs 4, and the number of crystal defects in the N-well region 2 per unit volume is made larger than that of in the P-well region 3 per unit volume. Therefore, even if the holes in the P-well region 3 flow into the N-well region 2, the possibility that the holes in the P-well region 3 of one MOSFET 4 flow into the P-well region 3 of the other MOSFET 4 may be avoided due to the recombination of the holes and the electrons at the crystal defects 6.

### Second Embodiment

In a second embodiment, the crystal defects 6 are formed only in the vicinity of a region immediately beneath the STI 5 in an N-well region 2.

FIG. 7 is a sectional view of a semiconductor storage device according to the second embodiment of the present invention. In FIG. 7, the common elements as used in FIG. 1, are designated by the same reference numbers as used in FIG. 1. Hereinafter, the different points from the first embodiment will be mainly described below.

The semiconductor storage device in FIG. 7 differs from that of the first embodiment in that crystal defects are formed in different locations in the N-well region 2. In the embodiment, the crystal defects 6 are formed only in the vicinities of the region immediately beneath the STIs 5 in the N-well region 2. Therefore, there is no crystal defect 6 in the region immediately beneath the locations on which the MOSFETs 4 are to be formed. Accordingly, it is possible to keep inverse characteristics of a pn-junction formed with a P-well region 3 and an N-well region in locations where the MOSFETs 4 are formed.

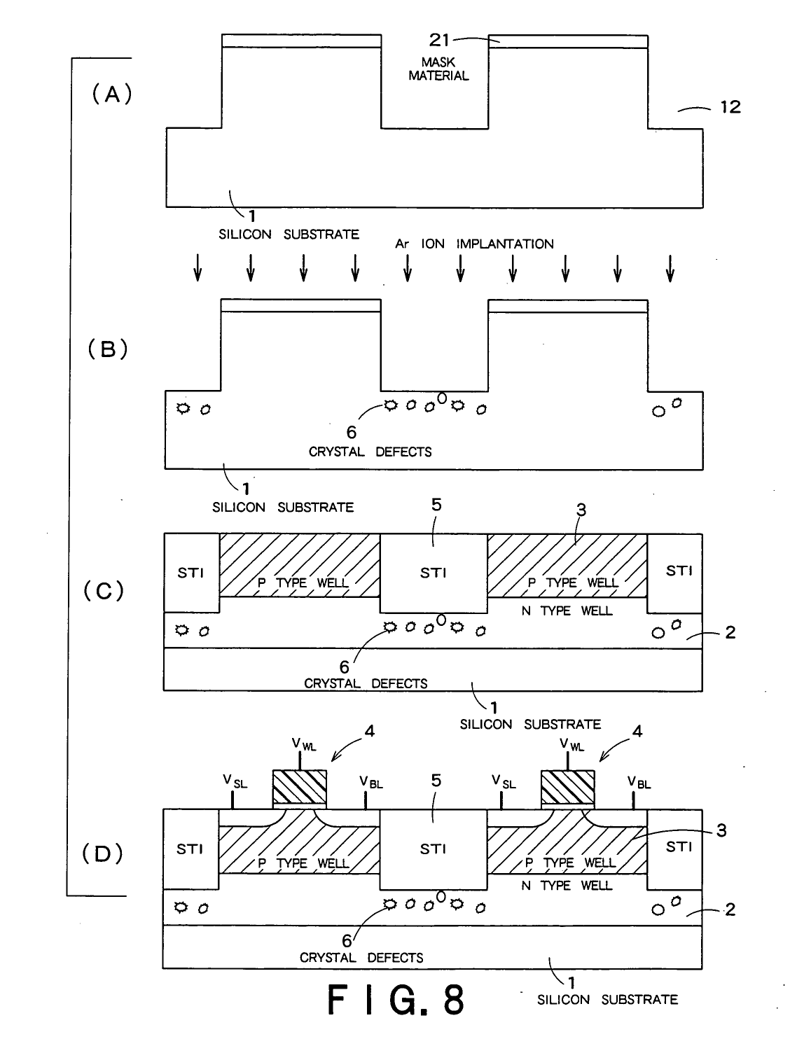

FIGS. 8A-8D are process drawings illustrating fabrication processes of the semiconductor storage device in FIG. 7. First, a mask material 21 for forming STIs 5 is attached on a silicon substrate 1, and trenches 12 are formed in locations on which STI 5 is to be formed (FIG. 8A).

Next, impurity ions (for example, argon) are ion-implanted in the top surface of the substrate. The conditions of the ion-implantation are, for example, at 100 KeV, 1×10¹⁵ cm⁻². Since the surroundings of the trenches 12 are covered with the mask material 21, the impurity ions are implanted only in the bottom surfaces of the trench 12, and crystal defects 6 are formed in the silicon substrate 1 (FIG. 8B).

Next, an insulating material is filled into the trenches 12. Impurity ions (for example, boron) are also ion-implanted, for example, at 60 KeV, 5×10¹³ cm⁻² to form P-well regions 3 on the both sides of STIs 5. Impurity ions (for example, phosphorus) are also ion-implanted, for example, at 240 KeV, 1×10¹⁴ cm⁻² to form P-well regions 3 on the both sides of STIs 5 (FIG. 8C). Next, MOSFETs 4 are formed on the P-well regions 3 (FIG. 8D).

In this way, in the second embodiment, crystal defects 6 are formed only in the locations immediately beneath STIs 5 in the N-well region 2. Therefore, the possibility that the crystal defects 6 affect the inverse characteristics of the MOSFETs 4 adjacent to the STIs 5 may be avoided. By providing the crystal defects 6, positive-hole current stops flowing from a P-well region 3 of a MOSFET 4 to the adjacent P-well region 3 through an N-well region 2.

### Third Embodiment

In a third embodiment, crystal defects 6 are formed in the N-well region 2 by utilizing the stresses applied to the corners of the bottom surfaces of STIs 5.

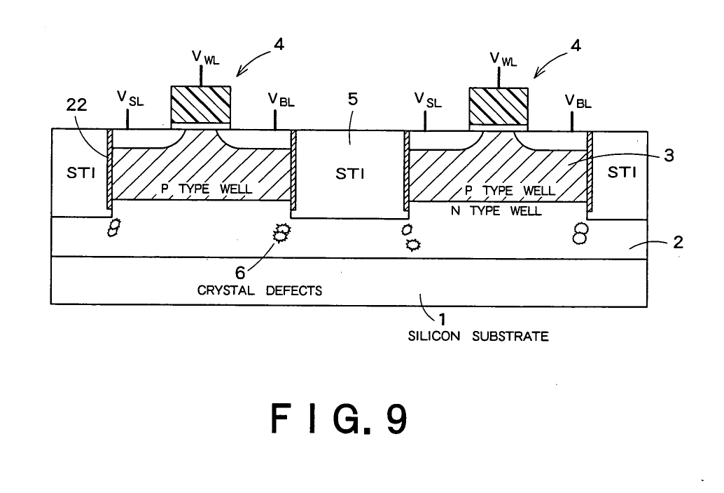

FIG. 9 is a sectional view of a semiconductor storage device according to the third embodiment of the present invention. In FIG. 9, the common elements as used in FIG. 1, are designated by the same reference numbers as used in FIG. 1. Hereinafter, different points from the first embodiment will be mainly described below.

The semiconductor storage device in FIG. 9 differs from those of the first embodiment and the second embodiment in that the crystal defects 6 are formed in different positions in the N-well region 2 and formed by a different forming method.

The STIs 5 in FIG. 9 have passivation films 22 formed along the side walls of the trenches 12. After forming the passivation films 22, when insulating films 23 are formed on the whole of the top surfaces of the substrate including the inside of the trenches 12, stresses applied to the corners of the bottom surface of the trench 12 are maximized. Therefore, even if impurity ions for forming crystal defects 6 are not implanted in the N-well region 2, crystal defects 6 may be formed in the N-well region 2 due to the stresses.

In case of FIG. 9, crystal defects 6 in the N-well region 2 are not formed immediately beneath MOSFETs 4. Therefore, the possibility that the crystal defects 6 affect the inverse characteristics of the MOSFETs 4 may be avoided.

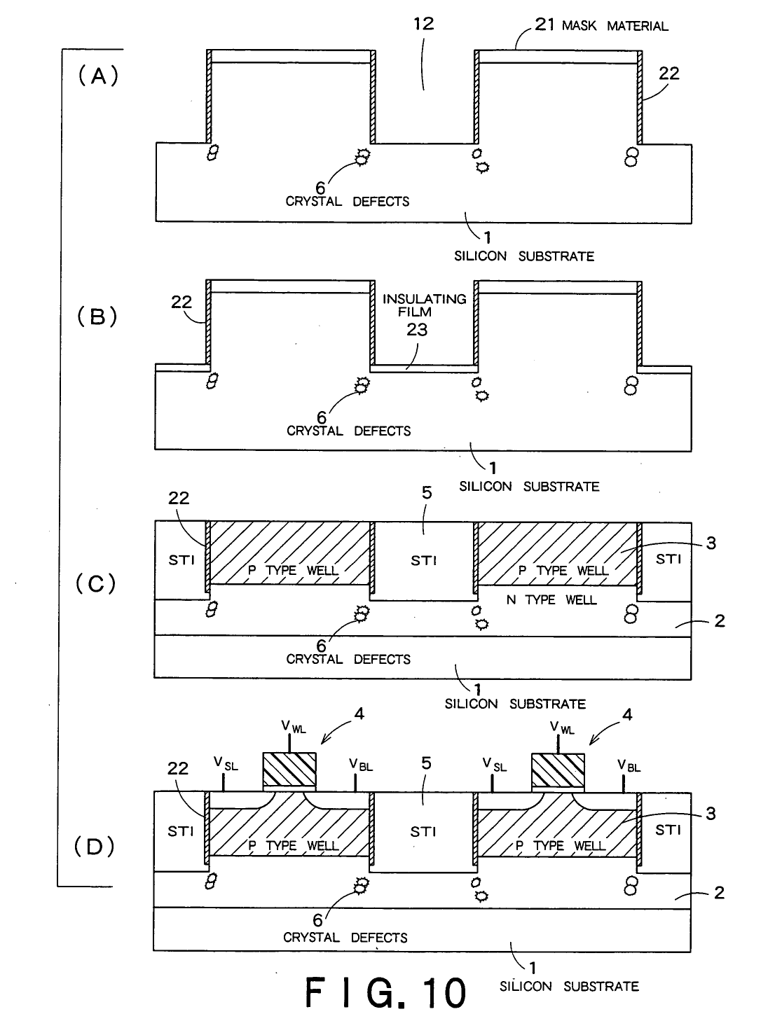

FIGS. 10A-10D are process drawings illustrating the fabrication processes of the semiconductor storage device in FIG. 9. First, a mask material 21 is attached on a silicon substrate 1, and trenches 12 are formed in the locations on which STI 5 is to be formed. Next, after depositing an oxidation-resistant film such as silicon nitride on the whole surfaces of the substrate, silicon nitride 22 to be a passivation material is formed on the sidewalls of the trenches 12 by applying RIE to the whole surfaces of the substrate (FIG. 10A). The thickness of the silicon nitride is, for example, 25 nm.

Next, crystal defects 6 are formed by thermal oxidation of the whole surfaces of the substrate. Therefore, the stresses occur at the corners of the bottom surfaces of the trenches 12 (FIG. 10B).

Next, impurity ions (for example, boron) are ion-implanted, for example, at 60 KeV, 5×10¹³ cm⁻² to form a P-well region 3. Impurity ions (for example, phosphorus) are also ion-implanted, for example, at 240 KeV, 1×10¹⁴ cm⁻² to form an N-well region 2 (FIG. 10C).

Next, gate electrodes 7, source electrodes 8, and drain electrodes 9 are formed on the P-well regions to form MOSFETs 4 (FIG. 10D).

In this way, in the third embodiment, crystal defects 6 are formed in the N-well region 2 utilizing stresses applied to the corners of the bottom surfaces of the trenches 12. Therefore, implantation process for the purpose of forming the crystal defects 6 may not be required, resulting in simplification of the fabrication processes.

What is claimed is:

1. A semiconductor storage device, comprising:
a first conductive type semiconductor region formed on a semiconductor substrate;
a plurality of second conductive type semiconductor regions formed separately from each other on the first conductive type semiconductor region;
a plurality of MOSFETs each formed on the plurality of second conductive type semiconductor regions; and
element isolating regions each formed between the adjacent second conductive type semiconductor regions, a bottom surface of which being located in the first conductive type semiconductor region,
wherein the number of crystal defects per unit volume in the first conductive type semiconductor region is larger than the number of the crystal defects per unit volume in the second conductive type semiconductor regions.

2. A semiconductor storage device according to claim 1,
wherein in the first conductive type semiconductor region, the number of the crystal defects per unit volume in a region located immediately beneath the element isolating region is larger than that of the crystal defects per unit volume in a region located immediately beneath the MOSFET.

3. A semiconductor storage device according to claim 1,
wherein the number of the crystal defects per unit volume in areas in the vicinity of corners of bottom surfaces of the element isolating regions is larger than that of the crystal defects per unit volume in an area other than the areas in the vicinity of corners in the first conductive type semiconductor region.

4. A semiconductor storage device according to claim 1,
wherein the first conductive type semiconductor region has crystal defects formed by implantation of impurity ions.

5. A semiconductor storage device according to claim 1,
wherein the first conductive type semiconductor region has crystal defects due to stresses applied to corners of bottom surfaces when an insulating material is filled in the trenches used for forming the element isolating regions.

6. A semiconductor storage device according to claim 5,
wherein each of the element isolating regions includes:
protective films formed along sidewalls of the trenches; and
an insulating film filled in the corresponding trench in which the protective films are formed.

7. A semiconductor storage device according to claim 1,
wherein the first conductive type semiconductor region has the crystal defects enough to cancel out majority carriers in the second conductive type semiconductor regions flowing into the first conductive type semiconductor region by recombining with majority carriers in the first conductive type semiconductor region at locations of the crystal defects in the first conductive type semiconductor region.

8. A semiconductor storage device according to claim 1,
wherein the MOSFETs are memory cells which store data by using fluctuation of threshold voltages in accordance with a difference between the numbers of the majority carriers in the second conductive type semiconductor regions.

9. A method of fabricating a semiconductor storage device, comprising:
forming a plurality of trenches separate from each other on a semiconductor substrate;
filling a insulating material in the trenches to form a plurality of element isolating regions;
injecting impurity ions of conductive type different from that of the semiconductor substrate to form a first conductive type semiconductor region which overlaps in the vicinity of bottom surfaces of the element isolating regions and second conductive type semiconductor regions on both sides of the element isolating regions on the first conductive type semiconductor region;
forming crystal defects in the first conductive type semiconductor region; and
forming MOSFETs in the plurality of second conductive type semiconductor regions.

10. A method of fabricating a semiconductor storage device according to claim 9,
wherein the number of crystal defects per unit volume in the first conductive type semiconductor region is larger than the number of the crystal defects per unit volume in the second conductive type semiconductor regions.

11. A method of fabricating a semiconductor storage device according to claim 9,
wherein the first conductive type semiconductor region has crystal defects formed by implantation of impurity ions.

12. A method of fabricating a semiconductor storage device according to claim 9,
wherein the first conductive type semiconductor region has the crystal defects enough to cancel out majority carriers in the second conductive type semiconductor regions flowing into the first conductive type semiconductor region by recombining with majority carriers in the first conductive type semiconductor region at locations of the crystal defects in the first conductive type semiconductor region.

13. A method of fabricating a semiconductor storage device according to claim 9,
wherein the MOSFETs are memory cells which store data by using fluctuation of threshold voltages in accordance with a difference between the numbers of the majority carriers in the second conductive type semiconductor regions.

14. A method of fabricating a semiconductor storage device, comprising:
forming a plurality of trenches separate from each other on a semiconductor substrate;
forming crystal defects below bottom surfaces of the trenches, and filling a insulating material in the trenches to form a plurality of element isolating regions;
injecting impurity ions of conductive type different from that of the semiconductor substrate to form a first conductive type semiconductor region which overlaps in the vicinity of bottom surfaces of the element isolating regions and second conductive type semiconductor regions on both sides of the element isolating regions on the first conductive type semiconductor region; and
forming MOSFETs in the plurality of second conductive type semiconductor regions.

15. A method of fabricating a semiconductor storage device according to claim 14,
wherein the number of the crystal defects per unit volume in areas in the vicinity of corners of bottom surfaces of the element isolating regions is larger than that of the crystal defects per unit volume in an area other than the areas in the vicinity of corners in the first conductive type semiconductor region.

16. A method of fabricating a semiconductor storage device according to claim 14,
wherein the first conductive type semiconductor region has crystal defects formed by implantation of impurity ions.

17. A method of fabricating a semiconductor storage device according to claim 14,
wherein the first conductive type semiconductor region has crystal defects due to stresses applied to corners of bottom surfaces when an insulating material is filled in the trenches used for forming the element isolating regions.

18. A method of fabricating a semiconductor storage device, according to claim 17,
Wherein a step of forming the element isolating regions, includes:
forming protective films along sidewalls in the trenches; and
filling the insulating films in the trenches in which the protective films are formed.

19. A method of fabricating a semiconductor storage device according to claim 14,
wherein the first conductive type semiconductor region has the crystal defects enough to cancel out majority carriers in the second conductive type semiconductor regions flowing into the first conductive type semiconductor region by recombining with majority carriers in the first conductive type semiconductor region at locations of the crystal defects in the first conductive type semiconductor region.

20. A method of fabricating a semiconductor storage device according to claim 14,
wherein the MOSFETs are memory cells which store data by using fluctuation of threshold voltages in accordance with a difference between the numbers of the majority carriers in the second conductive type semiconductor regions.
